(19) United States
(12) Patent Application Publication
(10) Pub. No.: US 2012/0139618 A1
(43) Pub. Date: Jun. 7, 2012

(54) PROJECTED CAPACITIVE TOUCH PANEL

(75) Inventor: Jane HSU, Taoyuan County (TW)

(73) Assignee: DERLEAD INVESTMENT LTD., Taipei (TW)

(21) Appl. No.: 13/163,113

(22) Filed: Jun. 17, 2011

(30) Foreign Application Priority Data
Dec. 3, 2010 (TW) 099223478

(51) Int. Cl. H03K 17/96

(52) U.S. Cl. 327/517

(57) ABSTRACT

A projected capacitive touch panel has an X-axis sensing layer and a Y-axis sensing layer. The X-axis sensing layer includes a plurality of sensing rows, each of which has two or more electrode sequences connected in parallel. The Y-axis sensing layer includes a plurality of sensing columns, each of which has two or more electrode sequences connected in parallel. Each electrode sequence has a plurality of Y-axis electrodes connected in series. Each of the Y-axis electrodes interposes or aligns with an X-axis electrode. The projected capacitive touch panel effectively reduces the impedance of each of the sensing columns and sensing rows, thus having higher sensitivity for a controller. The arrangement of the X-axis sensing layer and the Y-axis sensing layer is also useful for enlarging the size of the projected capacitive touch panel.

### BACKGROUND OF THE INVENTION

1. Field of the Invention

The invention relates to a projected capacitive touch panel and, in particular, to a touch-control panel that has lower internal resistance on each of the electrodes of the sensing layers.

2. Description of Related Art

The basic structure of a conventional projected capacitive touch panel is shown in FIG. 4. The projected capacitive touch panel includes a substrate 70, an X-axis sensing layer 80 and a Y-axis sensing layer 90.

The substrate 70 is transparent. The X-axis sensing layer 80 is above the substrate 70. The X-axis sensing layer 80 includes several sensing rows in horizontal direction. Each of the sensing rows has several rhombus X-axis electrodes 81 connected together. Each sensing row connects to an X-axis driving line 82.

The Y-axis sensing layer 90 is under the substrate 70. The Y-axis sensing layer includes several sensing columns in vertical direction. Each sensing column has several rhombus Y-axis electrodes 91 connected together. Moreover, each of the sensing columns connects to a Y-axis driving line 92.

Each of the Y-axis electrodes 91 on the Y-axis sensing layer 90 interposes or aligns with each of the X-axis electrodes 81. If the Y-axis electrodes 91 and the X-axis electrodes 81 are arranged alternately (as shown in FIG. 5), then the projected capacitive touch panel is of the self capacitance type. If the Y-axis electrodes 91 and the X-axis electrodes 81 are arranged in an overlapping way, i.e. aligning with each other, then the projected capacitive touch panel is of the mutual capacitance type.

Moreover, the X- and Y-axis driving lines 82, 92 of the X- and Y-sensing layers 80, 90 are connected with a controller for detecting variations in the capacitance at each capacitor node on the X- and Y-axis sensing layers 80, 90. Since the projected capacitive touch panel has high requirements in the matching between the sensing interface (X- and Y-axis sensing layers 80, 90) and the controller, the manufacturer has to consider the impedances of the X- and Y-axis driving lines 82, 92 and whether their internal resistances are uniform even when they are perpendicular to each other. This is because the internal resistances of the X- and Y-axis driving lines 82, 92 and whether they are uniform directly affect an output signal-to-noise (S/N) ratio of the touch panel.

According to the above description, the X-axis and Y-axis driving lines 82, 92 are concentrated on one side of the respective X-axis sensing layer 80 and the Y-axis sensing layer 90 for the connection with the controller. In this case, the distances between each of the X-axis and Y-axis driving lines 82, 92 to the controller cannot be the same but are instead quite different. That is, the X-axis and Y-axis driving lines 82, 92 have different lengths. The impedances of the X-axis and Y-axis driving lines 82, 92 are exactly proportional to their lengths. When the panel size becomes larger, the driving lines are longer and so the linear impedances are higher. Such an effect affects the sensitivity of the controller, resulting in possible errors.

### SUMMARY OF THE INVENTION

An objective of the invention is to provide a projected capacitive touch panel that can effectively reduce the internal resistance of electrode sequence on the sensing layer, thereby increasing the sensitivity of the controller in reading capacitance variations.

To achieve the above-mentioned objective, the disclosed projected capacitive touch panel includes: an X-axis sensing layer and a Y-axis sensing layer. The X-axis sensing layer has a plurality of sensing rows. One end of each of the sensing rows has an X-axis driving line. Each of the sensing rows has two or more X-axis electrode sequences in parallel. Each of the X-axis electrode sequences has a plurality of X-axis electrodes in series. The Y-axis sensing layer includes a plurality of sensing columns One end of each of the sensing columns has a Y-axis driving line. Each of the sensing columns has two or more Y-axis electrode sequences in parallel. Each of the Y-axis electrode sequences has a plurality of Y-axis electrodes in series, forming a capacitor with the corresponding X-axis electrodes.

Since the sensing rows and sensing columns on the X- and Y-axis sensing layers are composed of two or more electrode sequences connected in parallel, the internal resistance of the parallel electrode sequences becomes smaller, achieving the goal of lowering the internal resistance of the electrode sequence.

### BRIEF DESCRIPTION OF THE DRAWINGS

FIG. 1A is a perspective view of a preferred embodiment of the invention;

FIG. 1B is another perspective view of a preferred embodiment of the invention;

FIG. 2A is a planar view of the X-axis sensing layer in the preferred embodiment of the invention;

FIG. 2B is a planar view of the Y-axis sensing layer in the preferred embodiment of the invention;

FIG. 3 is a planar view of the overlapped X-axis and Y-axis sensing layers in the preferred embodiment of the invention;

FIG. 4 is a perspective view of a conventional projected capacitive touch panel; and

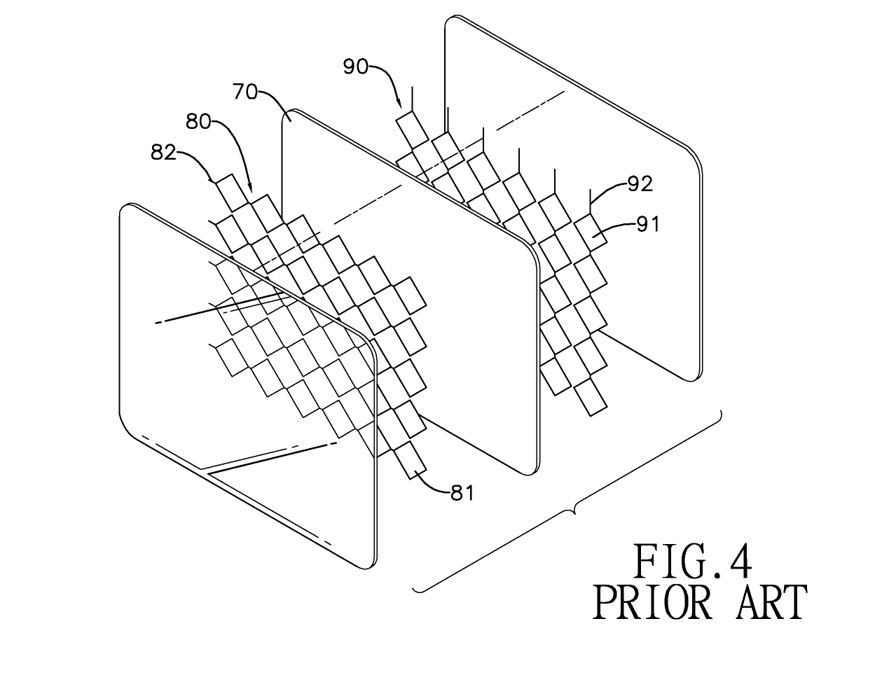

FIG. 5 is a planar view of a conventional projected capacitive touch panel.

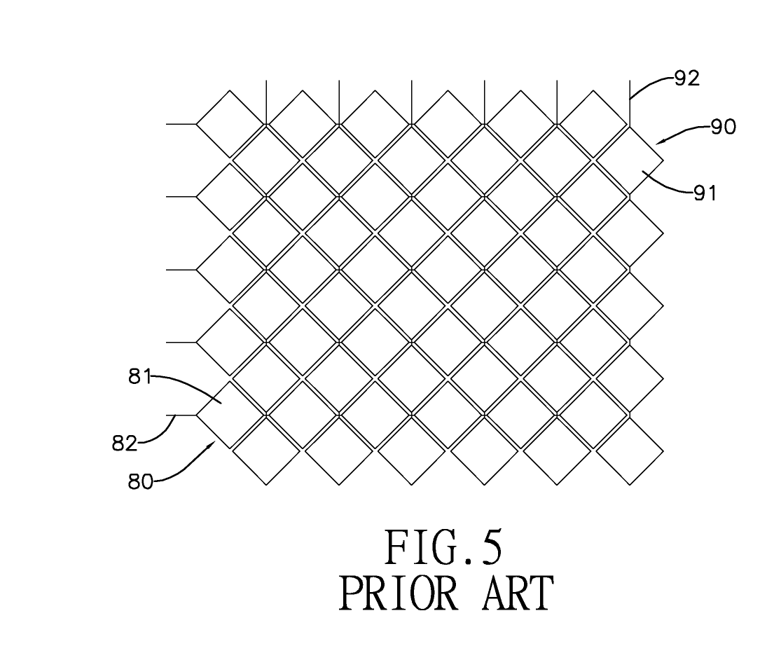

### DETAILED DESCRIPTION OF THE PREFERRED EMBODIMENT

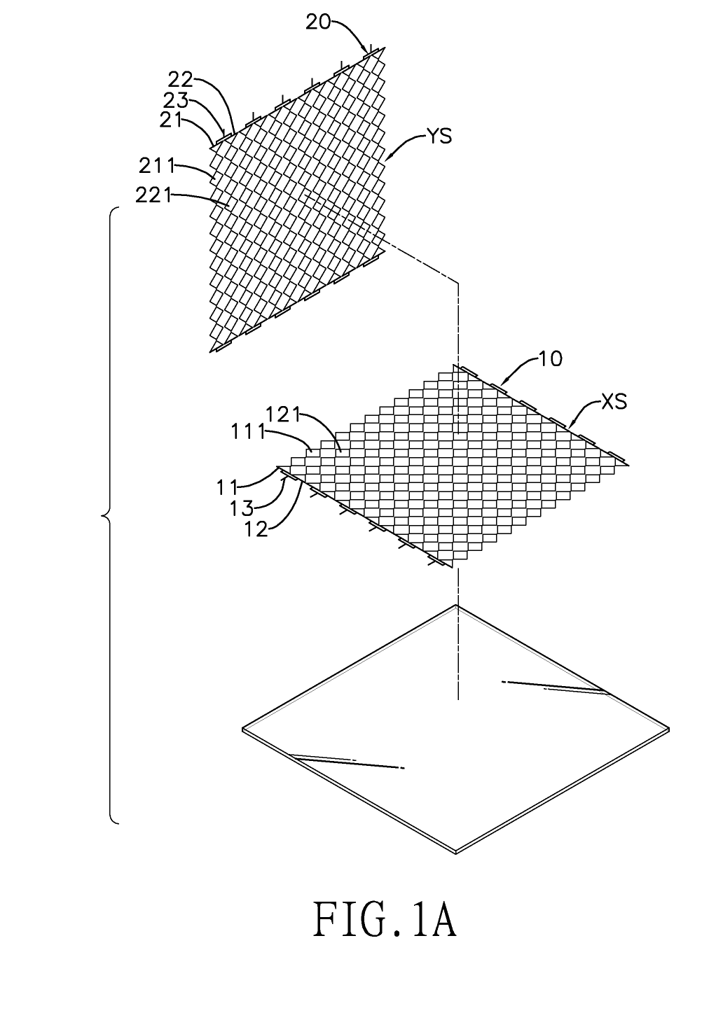

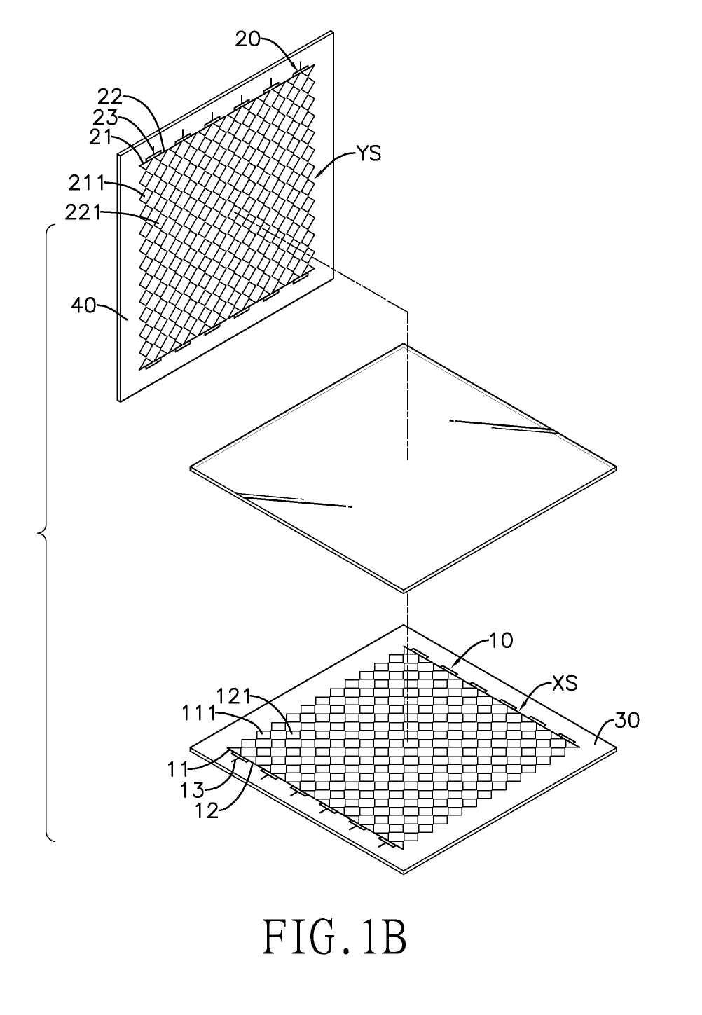

With reference to FIGS. 1A and 1B, a preferred embodiment of a projected capacitive touch panel comprises an X-axis sensing layer XS and a Y-axis sensing layer YS.

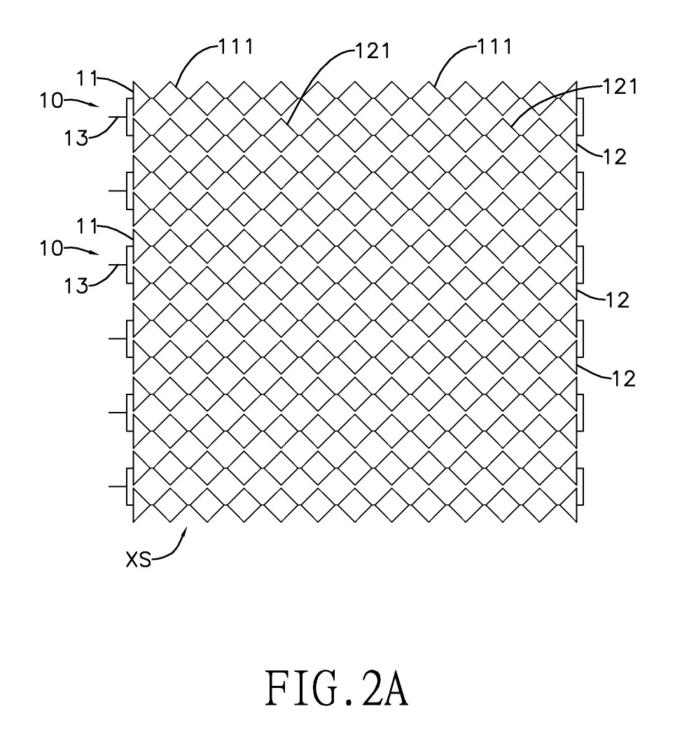

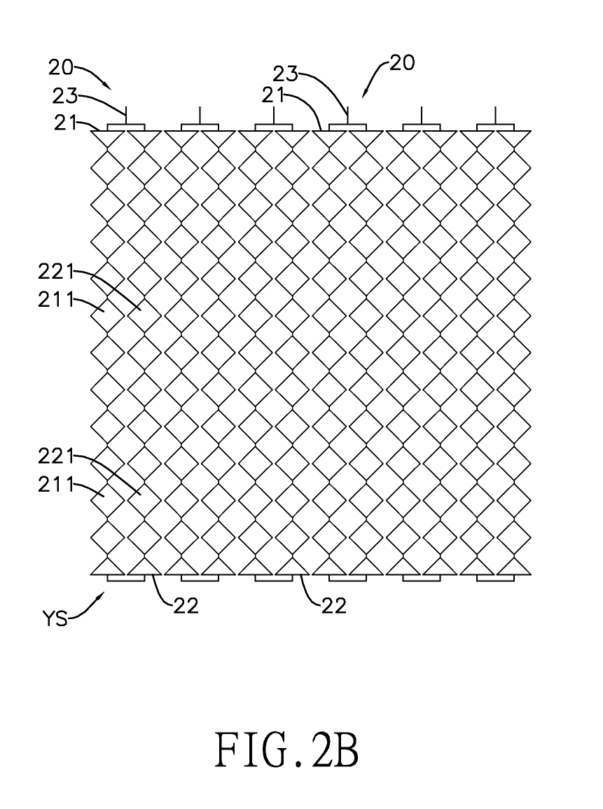

The X-axis sensing layer XS, as shown in FIG. 2A, has a plurality of sensing rows 10. One end of each of the sensing rows 10 has an X-axis driving line 13. Each of the sensing rows 10 has two or more X-axis electrode sequences 11, 12 connected in parallel. In this embodiment, each of the sensing rows 10 has two X-axis electrode sequences connected in parallel. Each of the X-axis electrode sequences 11, 12 has a plurality of X-axis electrodes 111, 121 connected in series.

The Y-axis sensing layer YS, as shown in FIG. 2B, has a plurality of sensing columns 20. One end of each of the sensing columns 20 has a Y-axis driving line 23. Each of the sensing columns 20 has two or more Y-axis electrode sequences 21, 22 connected in parallel. In this embodiment, each of the sensing columns 20 has two Y-axis electrode sequences 21, 22 connected in parallel. Each of the Y-axis electrode sequences 21, 22 has a plurality of Y-axis electrodes 211, 221 connected in series.

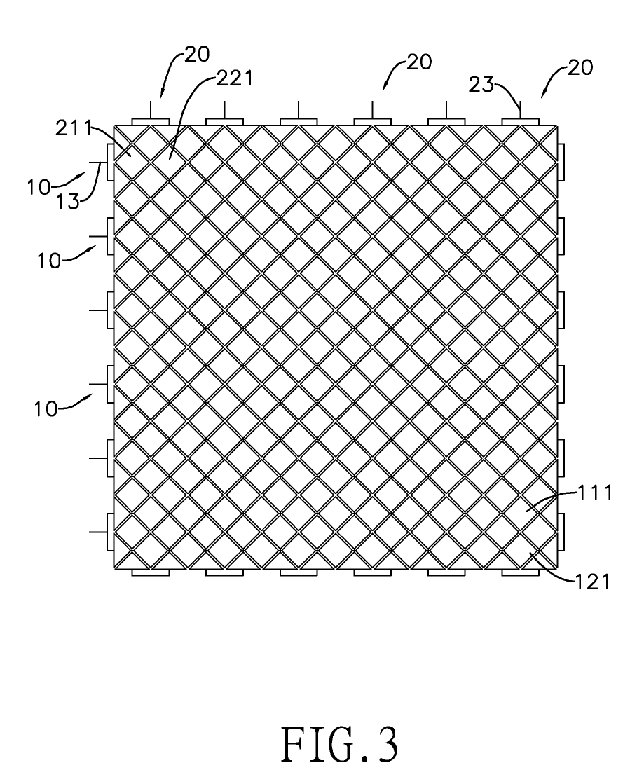

As shown in FIG. 1A, the X-axis sensing layer XS and the Y-axis sensing layer YS can be simultaneously formed on the same surface of a substrate. The X-axis electrodes 111, 121 of the X-axis sensing layer XS and the Y-axis electrodes 211, 221 of the Y-axis sensing layer YS are arranged alternately as shown in FIG. 3, thereby forming a self capacitance type projected capacitive touch panel.

With reference to FIG. 1B, in another embodiment, the X-axis sensing layer XS and the Y-axis sensing layer YS are formed on two opposite substrates 30, 40. Aside from those on both ends that form triangles, the X-axis electrodes 111, 121 and the Y-axis electrodes 211, 221 form rhombuses. In addition to the above forms, the X-axis sensing layer XS and the Y-axis sensing layer YS can be formed on opposite surfaces of a substrate or on opposite surfaces of two substrates, resulting in different kinds of self capacitance type projected capacitive touch panels.

Besides the self capacitance type, the invention can also be applied to the mutual capacitance type projected capacitive touch panel. In an embodiment, the X-axis sensing layer XS is formed on a surface of a substrate. The Y-axis sensing layer YS is formed on the opposite surfaces of the same substrate. Moreover, the Y-axis electrodes 211, 221 of the Y-axis sensing layer YS overlap with the X-axis electrodes 111, 121 on the substrate surface, thereby forming a mutual capacitance type projected capacitive touch panel. Moreover, the X-axis sensing layer XS and the Y-axis sensing layer YS can be formed on opposite surfaces of two substrates to form another kind of mutual capacitance type projected capacitive touch panel. In addition to triangles and rhombuses, the X-axis electrodes 111, 121 and the Y-axis electrodes 211, 221 can also form rectangles.

Furthermore, the two X-axis electrode sequences 11, 12 of each of the sensing rows 10 on the X-axis sensing layer XS are connected in parallel. The X-axis electrode sequences 11, 12 can be made of indium-tin-oxide (ITO) transparent electrodes and have individual internal resistances. The resistance of the two X-axis electrode sequences 11, 12 connected in parallel is smaller than the resistance of any X-axis electrode sequence. When the two X-axis electrode sequences 11, 12 are connected in parallel, the resistance of the sensing row 10 is lower. Likewise, the two Y-axis electrode sequences 21, 22 of each of the sensing columns 20 on the Y-axis sensing layer YS are also connected in parallel. Therefore, the resistance of the sensing column 20 is also reduced. This can increase the sensitivity of the controller.

As described above, whether the X-axis sensing layer XS and the Y-axis sensing layer YS are formed on one surface/opposite surfaces of the same substrate or opposite surfaces of two substrates, the manufacturer has to form X- and Y-axis driving lines 13, 23 connecting to each of the sensing rows 10 and the sensing columns 20. As the panel size becomes larger, the lengths of the X- and Y-axis driving lines 13, 23 of the sensing rows 10 and sending columns 20 near the panel edge are longer. As the distance to the controller connection port becomes larger, the linear impedance correspondingly becomes larger. At the same time, the internal resistances between the sensing rows 10 and between the sensing columns 20 are not uniform. This affects the accuracy of controller in reading. This is a primary cause that existing projected capacitive touch panel cannot be made larger.

Utilizing the disclosed technology, the internal resistance of the sensing rows 10 and the sensing columns 20 can be effectively reduced, thereby lowering the overall linear impedance from the sensing rows 10 and the sensing columns 20 to the controller. The accuracy of the controller can thus be relatively increased.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A projected capacitive touch panel comprising:
an X-axis sensing layer having a plurality of sensing rows, each of which is provided with an X-axis driving line on one end thereof and has two or more X-axis electrode sequences connected in parallel, each of the X-axis electrode sequences comprising a plurality of X-axis electrodes;
a Y-axis sensing layer having a plurality of sensing columns, each of which is provided with a Y-axis driving line on one end thereof and has two or more Y-axis electrode sequences connected in parallel, each of the Y-axis electrode sequences comprising a plurality of Y-axis electrodes;
wherein each of the Y-axis electrodes and each of the X-axis electrodes form a capacitor.

2. The projected capacitive touch panel as claimed in claim 1, wherein the X-axis electrodes on the X-axis sensing layer and the Y-axis electrodes on the Y-axis sensing layer are arranged alternately, thereby forming a self capacitance type projected capacitive touch panel.

3. The projected capacitive touch panel as claimed in claim 1, wherein the X-axis electrodes on the X-axis sensing layer and the Y-axis electrodes on the Y-axis sensing layer are arranged in an overlapping way, thereby forming a mutual capacitance type projected capacitive touch panel.

4. The projected capacitive touch panel as claimed in claim 2, wherein the X-axis sensing layer and the Y-axis sensing layer are formed on a surface of a substrate.

5. The projected capacitive touch panel as claimed in claim 2, wherein the X-axis sensing layer and the Y-axis sensing layer are formed on opposite surfaces of two substrates.

6. The projected capacitive touch panel as claimed in claim 3, wherein the X-axis sensing layer and the Y-axis sensing layer are formed on opposite surfaces of two substrates.

7. The projected capacitive touch panel as claimed in claim 2, wherein the X-axis sensing layer and the Y-axis sensing layer are formed on opposite surfaces of a substrate.

8. The projected capacitive touch panel as claimed in claim 3, wherein the X-axis sensing layer and the Y-axis sensing layer are formed on opposite surfaces of a substrate.

9. The projected capacitive touch panel as claimed in claim 2, wherein the X-axis electrodes of the X-axis sensing layer and the Y-axis electrodes of the Y-axis sensing layer form rhombuses.

10. The projected capacitive touch panel as claimed in claim 3, wherein the X-axis electrodes of the X-axis sensing layer and the Y-axis electrodes of the Y-axis sensing layer form rhombuses.

11. The projected capacitive touch panel as claimed in claim 3, wherein the X-axis electrodes of the X-axis sensing layer and the Y-axis electrodes of the Y-axis sensing layer form rectangles.
